(19) United States
(12) Patent Application Publication
(10) Pub. No.: US 2014/0232401 A1
(43) Pub. Date: Aug. 21, 2014

(54) MAGNETIC RESONANCE IMAGING APPARATUS AND METHOD FOR CALCULATING SPECIFIC ABSORPTION RATIO IN MAGNETIC RESONANCE IMAGING APPARATUS

(71) Applicants: KABUSHIKI KAISHA TOSHIBA, Tokyo (JP); TOSHIBA MEDICAL SYSTEMS CORPORATION, Otawara-Shi (JP)

(72) Inventor: Mitsuo TAKAGI, Otawara-Shi (JP)

(73) Assignees: KABUSHIKI KAISHA TOSHIBA, Tokyo (JP); TOSHIBA MEDICAL SYSTEMS CORPORATION, Otawara-Shi (JP)

(21) Appl. No.: 14/264,330

(22) Filed: Apr. 29, 2014

Related U.S. Application Data
(63) Continuation of application No. PCT/JP2013/073003, filed on Aug. 28, 2013.

(30) Foreign Application Priority Data
Aug. 29, 2012 (JP) 2012-188976

(51) Int. Cl. G01R 33/56

(52) U.S. Cl. CPC G01R 33/56
USPC 324/309

(57) ABSTRACT

A magnetic resonance imaging apparatus includes a shifted RF power calculation unit, a specific absorption ratio calculation unit and a display control unit. The shifted RF power calculation unit shifts RF power, when a weight of an object or an imaging region of the object is smaller than or equal to or smaller than a threshold, in accordance with a difference between the weight and the threshold to calculate shifted RF power. The specific absorption ratio calculation unit calculates, when the weight is smaller than or equal to or smaller than the threshold, a specific absorption ratio based on the threshold and the shifted RF power. The display control unit displays the specific absorption ratio on a display device.

### CROSS-REFERENCE TO RELATED APPLICATION

This application is a Continuation application of No. PCT/JP2013/73003, filed on Aug. 28, 2013, and the PCT application is based upon and claims the benefit of priority from Japanese Patent Application No. 2012-188976, filed on Aug. 29, 2012, the entire contents of which are incorporated herein by reference.

### FIELD

The present embodiment as an aspect of the present invention relates to a magnetic resonance imaging apparatus and a method for calculating specific absorption ratio in magnetic resonance imaging apparatus.

### BACKGROUND

A magnetic resonance imaging apparatus (MRI apparatus) measures an NMR signal (echo signal) generated by a spin of an atomic nucleus that forms an object, in particular, human tissue and visualizes morphologies and functions of a head, an abdomen, the four limbs, and other parts of a human body in a two-dimensional or three-dimensional manner. In imaging operation, the echo signal is encoded in terms of phase or frequency differently in accordance with a gradient magnetic field. The measured echo signal undergoes two-dimensional or three-dimensional Fourier transformation to form a reconstructed image.

In an MRI apparatus, the human body is irradiated with radiofrequency pulses (RF pulses) (RF pulses are applied to human body) for image collection. In recent years, widespread use of a high-speed imaging method in which a large number of RF pulses are radiated has increased power of RF pulses with which the human body is irradiated per unit time. Radiation of RF pulses primarily causes heat generation in the human body, resulting in an increase in body temperature. The increase in body temperature is considered to be up to a few degrees but may not be completely safe because the increase becomes a burden on a body temperature regulation mechanism of the human body.

A specific absorption ratio (SAR) is an indicator of the effect of RF pulses on the human body. The SAR is expressed in terms of the amount of heat generated per unit mass and absorbed by the human body (W/kg).

In a spherical model having a radius r and uniform electric conductivity σ, an SAR is calculated based on Expression (1) below.

SAR=σγ²B₀²α²D (1)

where Bₒ represents a strength of a static magnetic field, α represents a flip angle (rad), and D represents a duty cycle.

Since it is difficult to clinically measure an SAR associated with an individual human body, an SAR is actually calculated in a form of an estimated value (hereinafter referred to as “estimated SAR value”). The estimated SAR value can be calculated in several ways, such as a pulse energy method and a method for calculating the value based, for example, on tabulated past data and simulated results. In the pulse energy method, the estimated SAR value is calculated based on power of RF pulses with which the human body is actually irradiated and information on the patient.

Since both calculation methods cause the estimated SAR value to contain an error, the estimated SAR value must be displayed as a displayed value (hereinafter referred to as “displayed SAR value”), which is greater than a calculated value (hereinafter referred to as “calculated SAR value”) in consideration of the error. If the displayed SAR value greater than the calculated SAR value are displayed, the human body will be safer because a lower RF power limit is employed. In this case, however, a decrease in image quality and a decrease in the number of captured images per unit time occur as a tradeoff, resulting in a decrease in convenience of the MRI apparatus.

As a related art relating to the present invention, a technology for an MRI apparatus that reduces the amount of artifact and the value of specific absorption ratio has been disclosed.

In the pulse energy method, the amount of error in a calculation result is small in a case where a patient requires a large amount of RF power, whereas the amount of error increases in a case where the patient or a target site thereof does not require a large amount of RF power. Displaying the displayed SAR value greater than the calculated SAR value in consideration of the fact described above undesirably reduces convenience of the MRI apparatus.

In the method for calculating the estimated SAR value based on tabulated past data and simulated results, the amount of error does not change depending on a patient or a target site thereof. However, when RF pulses having RF power greater than intended (called 90° conditions) is applied for imaging for some reasons, safety undesirably lowers.

### BRIEF DESCRIPTION OF THE DRAWINGS

In accompanying drawings,

FIG. 1 is a schematic view showing a hardware configuration of an MRI apparatus according to a present embodiment;

FIG. 2 is a block diagram showing functions of the MRI apparatus according to the present embodiment;

FIGS. 3A to 3C are diagrams to explain a calculated value and a displayed SAR value;

FIGS. 4A to 4C are diagrams to explain the calculated value and the displayed SAR value;

FIG. 5 is a diagram showing a relationship between a weight and the displayed SAR value; and

FIG. 6 is a diagram showing a relationship between the displayed SAR value in related art and the displayed SAR value in the present embodiment.

### DETAILED DESCRIPTION

A magnetic resonance imaging apparatus (MRI apparatus) and a method for calculating specific absorption ratio in MRI apparatus according to the present embodiment will be described with reference to accompanying drawings.

To solve the above-described problems, the present embodiments provide the MRI apparatus, including: a shifted RF power calculation unit configured to shift RF power, when a weight of an object or an imaging region of the object is smaller than or equal to or smaller than a threshold, in accordance with a difference between the weight and the threshold to calculate shifted RF power; a specific absorption ratio calculation unit configured to calculate, when the weight is smaller than or equal to or smaller than the threshold, a specific absorption ratio based on the threshold and the shifted RF power; and a display control unit configured to display the specific absorption ratio on a display device.

To solve the above-described problems, the present embodiments provide the MRI apparatus, including: a specific absorption ratio calculation unit configured to calculate a specific absorption ratio based on a weight of an object or an imaging region of the object and correct the calculated specific absorption ratio based on the amount of correction according to the weight of the object to calculate a corrected specific absorption ratio; and a display control unit configured to display the corrected specific absorption ratio on a display device.

To solve the above-described problems, the present embodiments provide the method for calculating specific absorption ratio in MRI apparatus, including: shifting RF power, when a weight of an object or an imaging region of the object is smaller than or equal to or smaller than a threshold, in accordance with a difference between the weight and the threshold to calculate shifted RF power; calculating, when the weight is smaller than or equal to or smaller than the threshold, a specific absorption ratio based on the threshold and the shifted RF power; and displaying the specific absorption ratio on a display device.

The MRI apparatus and the method for calculating specific absorption ratio in MRI apparatus according to the present embodiment allows an increase in imaging average power, whereby image quality can be improved or the number of captured images per unit time (the number of slices) can be increased.

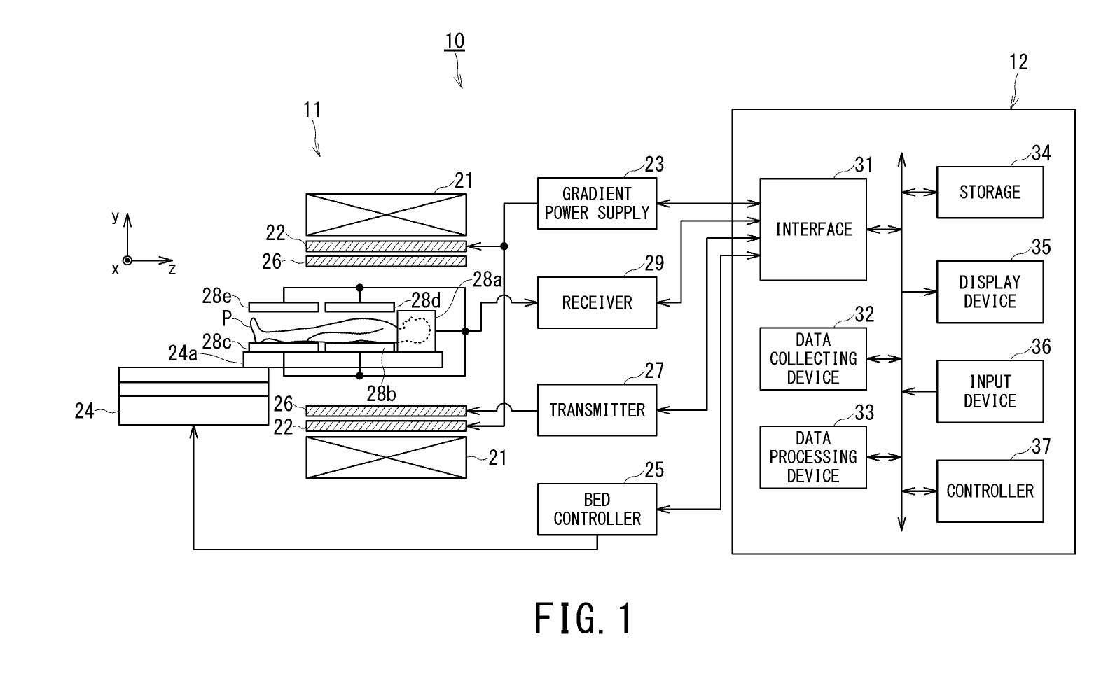

FIG. 1 is a schematic view showing a hardware configuration of the MRI apparatus according to the present embodiment.

FIG. 1 shows an MRI apparatus 10 according to the present embodiment that captures images of an imaging region of an object (patient) P. The MRI apparatus 10 is roughly formed of an imaging system 11 and a control system 12.

The imaging system 11 includes a static magnetic field magnet 21, a gradient magnetic field coil 22, a gradient power supply 23, a bed 24, a bed controller 25, a transmission coil 26, a transmitter 27, reception coils 28a to 28e, and a receiver 29.

The static magnetic field magnet 21 has a hollow cylindrical shape, is formed as an outermost portion around a chassis (not shown), and produces a uniform static magnetic field in an internal space. Examples of the static magnetic field magnet 21 include a permanent magnet and a superconducting magnet.

The gradient magnetic field coil 22 has a hollow cylindrical shape and is disposed inside the static magnetic field magnet 21. The gradient magnetic field coil 22 is a combination of three coils corresponding to x, y, and z axes perpendicular to each other, and the three coils receive respective currents supplied from the gradient power supply 23, which will be described later, to produce gradient magnetic fields a strength of which changes along the x, y, and z axes. The Z-axis direction coincides with a direction of the static magnetic field.

The gradient magnetic fields along the x, y, and z axes produced by the gradient magnetic field coil 22 correspond, for example, to a readout gradient magnetic field Gr, a phase encode gradient magnetic field Ge, and a slice selection gradient magnetic field Gs, respectively. The readout gradient magnetic field Gr is used to change a frequency of an NMR (nuclear magnetic resonance) signal in accordance with a spatial position. The phase encode gradient magnetic field Ge is used to change a phase of the NMR signal in accordance with the spatial position. The slice selection gradient magnetic field Gs is used to arbitrarily determine a cross section to be imaged.

The gradient power supply 23 supplies the gradient magnetic field coil 22 with currents based on pulse sequence execution data sent from the control system 12.

The bed 24 includes a top plate 24a, on which the object P is placed. The bed 24 inserts the top plate 24a on which the object P is placed into a cavity (imaging field) of the gradient magnetic field coil 22 under control of the bed controller 25, which will be described later. The bed 24 is typically so installed that a longitudinal direction thereof is parallel to a central axis of the static magnetic field magnet 21.

The bed controller 25 drives the bed 24 to move the top plate 24a in the longitudinal direction and upward and downward directions.

The transmission coil 26 is disposed inside the gradient magnetic field coil 22 and receives radio frequency pulses supplied from the transmitter 27 to produce a high-frequency magnetic field.

The transmitter 27 transmits radio frequency pulses corresponding to a Larmor frequency to the transmission coil 26 based on the pulse sequence execution data sent from the control system 12.

The reception coils 28a to 28e are disposed inside the gradient magnetic field coil 22 and receive NMR signals radiated from an imaging region of the object P under an influence of the radio frequency magnetic field. Each of the reception coils 28a to 28e is an array coil having a plurality of element coils that receive magnetic resonance signals emitted from the imaging region of the object P. Having received an NMR signal, each of the element coils outputs the received NMR signal to the receiver 29.

The reception coil 28a is a head coil located around a head of the object P. Each of the reception coils 28b and 28c is a spine coil disposed between a back of the object P and the top plate 24a. Each of the reception coils 28d and 28e is an abdomen coil disposed at an abdomen of the object P.

The receiver 29 produces NMR signal data based on the NMR signals outputted from the reception coils 28a to 28e based on the pulse sequence execution data sent from the control system 12. Having produced the NMR signal data, the receiver 29 transmits the NMR signal data to the control system 12.

The receiver 29 has a plurality of reception channels for receiving the NMR signals outputted from the plurality of element coils that form each of the reception coils 28a to 28e. When the control system 12 notifies the receiver 29 of an element coil to be used for imaging, the receiver 29 assigns one of the reception channels to the notified element coil so that an NMR signal outputted from the notified element coil is received.

The control system 12, for example, controls the entire MRI apparatus 10, collects data, and reconstructs an image. The control system 12 includes an interface 31, a data collecting device 32, a data processing device 33, a storage 34, a display device 35, an input device 36, and a controller 37.

The interface 31 is connected to the gradient power supply 23, the bed controller 25, the transmitter 27, and the receiver 29 and controls input and output signals transmitted between the components connected to the interface 31 and the control system 12.

The data collecting device 32 collects the NMR signal data transmitted from the receiver 29 via the interface 31. Having collected the NMR signal data, the data collecting device 32 stores the collected NMR signal data in the storage 34.

The data processing device 33 performs post processing, that is, Fourier transform or any other type of reconstruction processing on the NMR signal data stored in the storage 34 to produce spectrum data or image data on a desired nuclear spin in the imaging region of the object P. When a positioning image is captured, the data processing device 33 produces, based on an NMR signal received by each of the plurality of element coils that form each of the reception coils 28a to 28e, profile data on an element coil basis that represent a distribution of the NMR signal in the direction in which the element coils are arranged. The data processing device 33 then stores the produced variety of data in the storage 34.

The storage 34 stores the NMR signal data collected by the data collecting device 32, the image data produced by the data processing device 33, and other data for each object P. The storage 34 further stores angle information and slicing condition setting information.

The display device 35 displays a variety of types of information, such as the spectrum data or image data produced by the data processing device 33. The display device 35 can be a liquid crystal display or any other suitable display device.

The input device 36 receives a variety of types of operation and information inputs from an operator. The input device 36 can be a mouse, a trackball, or any other pointing device, a mode switcher or any other selection device, or a keyboard or any other input device as appropriate.

The controller 37 has a CPU (central processing unit), a memory, and other components (not shown) and oversees and controls the MRI apparatus 10 by controlling the portions described above.

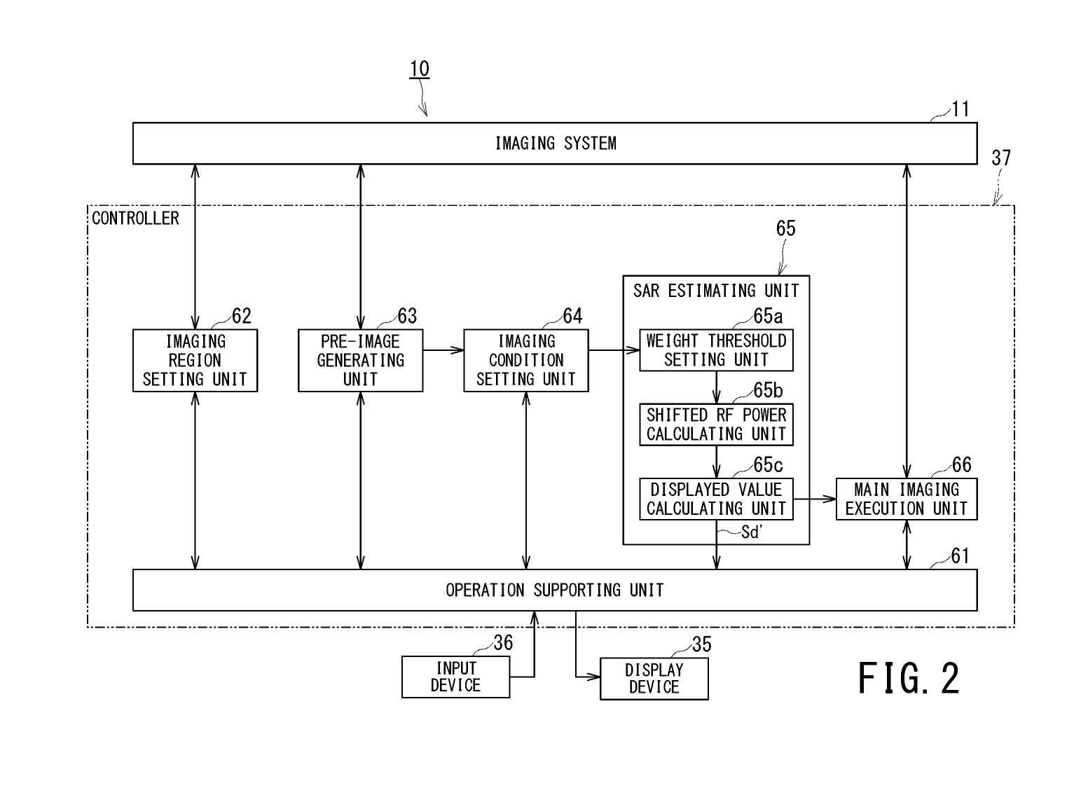

FIG. 2 is a block diagram showing functions of the MRI apparatus 10 according to the present embodiment.

When the CPU in the controller 37 executes a program, the MRI apparatus 10 functions as an operation supporting unit 61, an imaging region setting unit 62, a pre-image generating unit 63, an imaging condition setting unit 64, an SAR estimating unit 65, and a main imaging execution unit 66, as shown in FIG. 2. A description will be made of a case where the components 61 to 66 of the MRI apparatus 10 function as software, but part or the entire of the components 61 to 66 may be implemented as circuits in the MRI apparatus 10.

The operation supporting unit 61 is an interface that interfaces between the components 62 to 66 and the display device 35 and the input device 36, such as a GUI (graphical user interface).

The imaging region setting unit 62 has a function of setting one or more imaging regions (imaging positions) of the object P (shown in FIG. 1). For example, the imaging region setting unit 62 sets an imaging region based on an input signal that the operator inputs to an imaging condition edit screen by using the input device 36. When a desired imaging region is set among the plurality of imaging regions, the imaging condition setting unit 64, which will be described later, sets imaging conditions (such as sequence and scan conditions) corresponding to the set imaging region. That is, at the time when the imaging condition setting unit 64, which will be described later, sets imaging conditions, an imaging region has been already set before the imaging conditions are set. Further, for example, the imaging region setting unit 62 sets an imaging region by recognizing a structure of volume data produced in a volume scan process carried out by the pre-image generating unit 63, which will be described later. Further, for example, the imaging region setting unit 62 sets an imaging region based on not only a coil element in the reception coils 28a to 28e that has been set to receive an NMR signal based on an input signal that the operator has inputted by using the input device 36 but also orientation of the object P (shown in FIG. 1) that enters the chassis (head first or feet first).

The pre-image generating unit 63 has a function of controlling action of the imaging system 11 in accordance with imaging conditions for pre-imaging prior to final imaging (imaging for setting parameters of imaging conditions for final imaging) to capture images of the imaging region set by the imaging region setting unit 62 so as to generate original images that are cross-sectional images. Specifically, the pre-image generating unit 63 generates one of three orthogonal cross-sectional images, an axial (AX) image, a sagittal (SG) image, and a coronal (CO) image, as an original image. The following description will be made assuming that the pre-image generating unit 63 generates sagittal images as original images. Sagittal images are displayed on the display device 35 via the operation supporting unit 61.

The pre-image generating unit 63 may perform reconstruction by using axial images and coronal images, which are others of the three orthogonal cross-sectional images, based on sagittal images. Coronal and axial images are displayed on the display device 35 via the operation supporting unit 61.

The imaging condition setting unit 64 has a function of setting imaging conditions on the imaging condition edit screen.

The SAR estimating unit 65 has a function of calculating a displayed SAR value Sd′ relating to a weight of an imaging region (partial body weight) of the object P (shown in FIG. 1) based on the imaging conditions set by the imaging condition setting unit 64 by using a pulse energy method, a calorimetry method, or a Q-value measurement method. The weight of the imaging region is calculated based on a weight of the object P (overall weight), a height thereof, and other factors. The displayed SAR value Sd′ calculated by the SAR estimating unit 65 is displayed on the display device 35 via the operation supporting unit 61. The imaging condition setting unit 64 may change and reset the imaging conditions in such a way that the displayed SAR value Sd′ is lower than or equal to a threshold. A method for calculating the displayed SAR value Sd′ by using the SAR estimating unit 65 will be described later in detail.

The main imaging execution unit 66 has a function of executing final imaging for diagnostic at the imaging region set by the imaging region setting unit 62 when the displayed SAR value Sd′ calculated by the SAR estimating unit 65 is smaller than or equal to (or smaller than) an SAR threshold (limit) by controlling the action of the imaging system 11 in accordance with the imaging conditions set by the imaging condition setting unit 64.

The method for calculating the displayed SAR value Sd′ by using the SAR estimating unit 65 will subsequently be described. The description will be made of a method for calculating the displayed SAR value Sd′ based on the pulse energy method by way of example.

A description will first be made of a method in related art for calculating a displayed SAR value Sd relating to a weight of an imaging region of the object P (partial body weight), based on the pulse energy method.

In a method in related art for calculating the displayed SAR value Sd, a calculated SAR value Sc is determined from Expression (2) below based on the following two values: a value R obtained by subtracting a measured RF power (amount of generated heat) Rn absorbed by the imaging region under no load (with no object) from a measured RF power (amount of generated heat) Re absorbed under a load (with object); and a weight B of the imaging region. The RF power Re is measured and monitored at a time of imaging based on an output from the transmission coil 26 (RF amplifier) shown in FIG. 1. The RF power Re may instead be estimated from the imaging conditions set by the imaging condition setting unit 64.

Sc=(Re−Rn)/B=R/B (2)

It is then necessary to produce the displayed SAR value Sd based on Expression (2) described above in consideration of a measurement error of the RF power Re absorbed by the imaging region under a load.

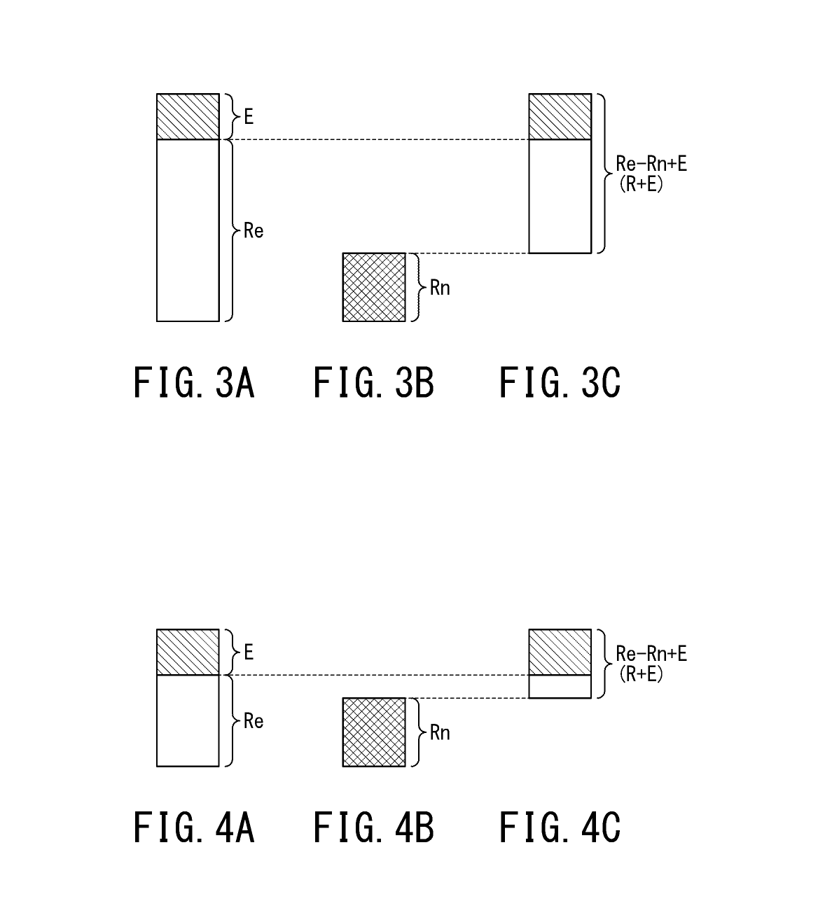

FIGS. 3A to 3C and FIGS. 4A to 4C are diagrams to explain the calculated value Sc and the displayed SAR value Sd. FIGS. 3A to 3C show a case using RF power for a relatively wide imaging area, whereas FIGS. 4A to 4C show a case using RF power for relatively narrow imaging area, such as in head imaging.

FIGS. 3A and 4A show the RF power Re absorbed by the imaging region under a load and an error E produced in measurement thereof. The error E is determined in advance to be a % of the RF power Re. FIGS. 3B and 4B show the RF power Rn absorbed by the imaging region under no load (including an error produced in measurement thereof). In these cases, a numerator of the displayed SAR value Sd shown in Expression (3) below is obtained by adding the error E to a value R obtained by subtracting the RF power Rn absorbed by the imaging region under no load from the RF power Re absorbed by the imaging region under a load, as shown in FIGS. 3C and 4C.

Sd={(Re−Rn)+E}/B=(R+E)/B (3)

In a case where the object P (shown FIG. 1) is, for example, a child and small and hence an imaging region is small, or in a case where an imaging target area is relatively narrow, the weight B of the imaging region is small, and the error E in Expression (3) described above greatly affects the displayed SAR value Sd, and the displayed SAR value Sd becomes excessively large. In these cases, the displayed SAR value Sd therefore becomes excessively large. When the displayed SAR value Sd is excessively large, the number of slicing in imaging is undesirably limited or TR (repetition time) is undesirably extended.

For example, in FIGS. 3A to 3C, when the RF power R is 30 [W], the error E is 15 [W], and the weight of an imaging region is 30 [kg], the calculated SAR value Sc is calculated to be 1.0 [W/kg] by using Expression (2) described above, and the displayed SAR value Sd is calculated to be 1.5 [W/kg] by using Expression (3) described above. Further, in FIGS. 4A to 4C, when the RF power R is [W], the error E is 15 [W], and the weight of an imaging region is 10 [kg], the calculated SAR value Sc is calculated to be 1.0 [W/kg] by using Expression (2) described above, and the displayed SAR value Sd is calculated to be 2.5 [W/kg] by using Expression (3) described above.

That is, even when the calculated SAR values Sc are calculated to be a same value or 1.0 [W/kg] by using Expression (2) described above, the displayed SAR value Sd is calculated to be 1.5 [W/kg] by using Expression (3) described above in one case and calculated to be 2.5 [W/kg] by using Expression (3) described above in another case. That is, even when two calculated SAR values Sc are equal to each other, displayed SAR values Sd may differ from each other. In a case where an imaging region is small or an imaging area is relatively narrow, the displayed SAR value Sd is excessively large as compared with opposite cases.

In view of the fact described above, in the present embodiment, when an imaging region is small or an imaging area is relatively narrow, the displayed SAR value Sd′ that is not excessively large is provided even when an imaging target area is relatively narrow, unlike the excessively large displayed SAR value Sd is provided in related art when an imaging target area is relatively narrow.

A method for calculating a displayed SAR value Sd′ in the present embodiment will subsequently be described.

The description with reference to FIG. 2 now resumes. The SAR estimating unit 65 includes a weight threshold setting unit 65a, a shifted RF power calculating unit 65b, and a displayed value calculating unit 65c.

The weight threshold setting unit 65a has a function of setting a weight threshold Bt that allows a stable displayed SAR value Sd to be provided on an imaging region basis. The weight threshold setting unit 65a does not necessarily set the weight threshold Bt of the weight of an imaging region set by the imaging region setting unit 62 at a timing of imaging but may set the weight threshold Bt in advance on an imaging region basis.

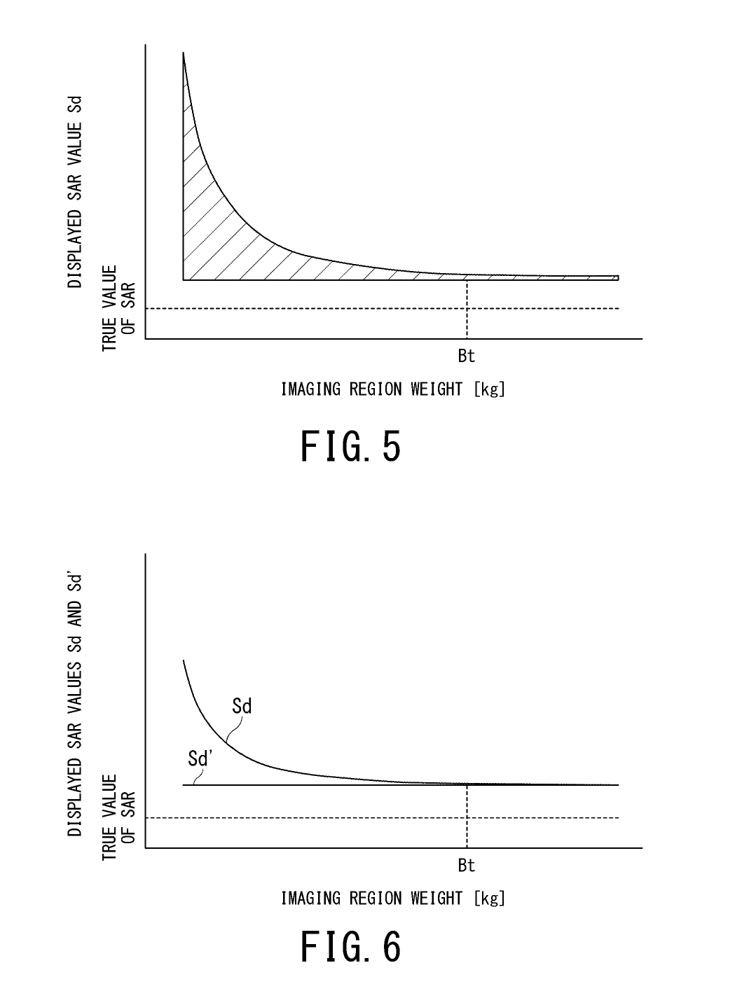

FIG. 5 is a diagram showing a relationship between the weight and the displayed SAR value Sd.

FIG. 5 is a simulated distribution diagram obtained in head imaging by substituting RF power R for each head weight B into Expression (3) described above and plotting the resultant displayed SAR value Sd. The plotted points are present in a hatched portion shown in FIG. 5. Based on FIG. 5, the displayed SAR value Sd is stable at a fixed value greater than at least a true value of SAR when the head weight B is greater than Bt [kg]. The reason for this is that when the head weight Bt is greater than Bt [kg], the RF power R typically increases with the head weight B. On the other hand, based on FIG. 5, the displayed SAR value Sd varies when the head weight B is smaller than or equal to Bt [kg]. The reason for this is that when the head weight B is smaller than or equal to Bt [kg], generally, the RF power R varies as the head weight B changes. The head weight B that allows the stable displayed SAR value Sd is provided is therefore set as the weight threshold Bt. A weight threshold Bt of the weight of an imaging region that allows the stable displayed SAR value Sd is provided is set on an imaging region basis.

The description with reference to FIG. 2 now resumes again. The shifted RF power calculating unit 65b has a function of shifting, when the weight B of an imaging region set by the imaging region setting unit 62 is smaller than or equal to (or smaller than) the weight threshold Bt set by the weight threshold setting unit 65a, the RF power R (Expression (3) described above) in accordance with a difference between the weight B of the imaging region and the weight threshold Bt to calculate a corrected shifted RF power R′. The shifted RF power calculating unit 65b calculates, when the weight B of an imaging region is smaller than or equal to the weight threshold Bt set by the weight threshold setting unit 65a, a difference (or ratio) between two RF power values obtained by substituting the weight B of the imaging region and the weight threshold Bt into an expression that relates the weight of an imaging region to the RF power (regression expression based on distribution diagram in which RF power is plotted for each weight of imaging region). The shifted RF power calculating unit 65b adds the difference (or ratio) between the calculated two RF power values to actual RF power R (or multiples the latter by the former) to calculate shifted RF power R′.

The displayed value calculating unit 65c substitutes, when the weight B of the imaging region is greater than the weight threshold Bt set by the weight threshold setting unit 65a, the weight B of the imaging region and the RF power R into Expression (3) described above to calculate the displayed SAR value Sd, whereas when the weight B of the imaging region is smaller than or equal to the weight threshold Bt, substituting the weight threshold Bt and the shifted RF power R′ into Expression (4) below, which is a variation of Expression (3) described above, to calculate the displayed SAR value Sd′.

Sd′=(R′+E)/Bt (4)

FIG. 6 is a diagram showing a relationship between the displayed SAR value Sd in related art and the displayed SAR value Sd′ in the present embodiment.

FIG. 6 shows the following two regression curves obtained in head imaging for each head weight B: a regression curve based on the distribution diagram in which the displayed SAR value Sd determined by Expression (3) described above is plotted (FIG. 5); and a regression curve based on a distribution diagram in which the displayed SAR value Sd′ determined by Expression (4) described above is plotted when the head weight is smaller than or equal to the weight threshold Bt. When the head weight is smaller than or equal to the weight threshold Bt, the displayed SAR value Sd in related art becomes excessively large as the head weight B decreases, as shown in FIG. 6. On the other hand, the displayed SAR value Sd′ in the present embodiment is stable irrespective of the head weight B at a fixed value greater than at least the true value of SAR.

In head imaging, consider now a case where the head weight B is 5 [kg] and the RF power R happens to be about 2 [kW] (typically about 1.4 [kW]). In this case, not only the displayed SAR value Sd but also the displayed SAR value Sd′ exceeds 3.2 [W/kg], which is a limit of a SAR of a head part. In this case, the main imaging execution unit 66 (shown in FIG. 2) does not perform imaging.

Alternatively, the SAR estimating unit 65 uses the RF power R and the amounts of correction F(B) to H(B), which vary in accordance with the weight B of the imaging region, to calculate displayed SAR values Sd′ based on Expression (5), (6), or (7) below in order to directly correct the displayed SAR value Sd determined by Expression (4) described above. In this case, no shifted RF power R′ (expressed by Expression (4) described above) needs to be determined.

Sd′={R+E}/B+F(B) (5)

Sd′={R+E+G(B)}/B (6)

Sd′={R+E}/{B+H(B)} (7)

The amounts of correction F(B) to H(B) in Expressions (5) to (7) described above are so set that the displayed SAR value Sd′ remains fixed irrespective of the weight B of the imaging region that is smaller than or equal to the weight threshold Bt as shown in FIG. 6. On the other hand, when the weight B of the imaging region is greater than or equal to (or greater than) the weight threshold Bt, the amounts of correction F(B) to H(B) in Expressions (5) to (7) described above are all set at “0”. In this case, a table that relates values of the weight B of the imaging region to the amounts of correction F(B) to H(B) may be produced in advance, and the amounts of correction F(B) to H(B) may be acquired by referring to the actual weight B of the imaging region in the table.

The description with reference to FIG. 2 now resumes again. It is noted that the main imaging execution unit 66 performs imaging in accordance with the RF power R set by the imaging condition setting unit instead of the shifted RF power R′ calculated by the shifted RF power calculating unit 65b.

It is noted that the displayed SAR value is not limited to the displayed SAR value Sd′ relating to the weight (partial weight) of an imaging region of the object P (shown in FIG. 1). The displayed SAR value may relate to the weight (overall weight) of the object P (shown in FIG. 1). When the displayed SAR value is a displayed SAR value Td′ relating to a weight W of the object P, the displayed SAR value Td′ is calculated from Expression (8) below, which is a variation of Expression (4) described above, by using a weight threshold Wt for the object P.

Td′=(R′+E)/Wt (8)

When the displayed SAR value is the displayed SAR value Td′ relating to the weight W of the object P (shown in FIG. 1), the displayed SAR value Td′ is alternatively calculated from Expressions (9) to (11) below, which are variations of Expressions (5) to (7) described above. In this case, no shifted RF power R′ (expressed by Expression (4) described above) needs to be determined.

Td′={R+E}/W+I(W) (9)

Td′={R+E+J(W)}/W (10)

Td′={R+E}/{W+K(W)} (11)

The amounts of correction I(W) to K(W) in Expressions (9) to (11) described above are so set that the displayed SAR value Td′ remains fixed irrespective of the weight W of the object P that is smaller than or equal to the weight threshold Wt. On the other hand, when the weight W of the object P is greater than or equal to (or greater than) the weight threshold Wt, the amounts of correction I(W) to K(W) in Expressions (9) to (11) described above are all set at “0”. In this case, a table that relates values of the weight W of the object P to the amounts of correction I(W) to K(W) may be produced in advance, and the amounts of correction I(W) to K(W) may be acquired by referring to the actual weight W of the object P in the table.

According to the MRI apparatus 10 of the present embodiment, instead of excessively large displayed SAR values Sd and Td in related art in a case where an imaging region is small or an imaging target area is relatively narrow, calculated SAR values Sd′ and Td′ that are not excessively large can be provided even when an imaging target area is relatively narrow. Therefore, according to the MRI apparatus 10 of the present embodiment, imaging average power can be increased, whereby image quality can be improved or the number of captured images (number of slices) per unit time can be increased.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
a shifted RF power calculation unit configured to shift RF power, when a weight of an object or an imaging region of the object is smaller than or equal to or smaller than a threshold, in accordance with a difference between the weight and the threshold to calculate shifted RF power;
a specific absorption ratio calculation unit configured to calculate, when the weight is smaller than or equal to or smaller than the threshold, a specific absorption ratio based on the threshold and the shifted RF power; and
a display control unit configured to display the specific absorption ratio on a display device.

2. The magnetic resonance imaging apparatus according to claim 1, wherein
the shifted RF power calculation unit substitutes, when the weight is smaller than or equal to or smaller than the threshold, the weight and the threshold into an expression that relates the weight to the RF power to produce two RF power values, calculates a difference between the two RF power values, and adds the calculated difference between the two RF power values to the RF power before shifted to calculate the shifted RF power.

3. The magnetic resonance imaging apparatus according to claim 1, wherein
the shifted RF power calculation unit substitutes, when the weight is smaller than or equal to or smaller than the threshold, the weight and the threshold into an expression that relates the weight to the RF power to produce two RF power values, calculates a ratio between the two RF power values, and multiplies the RF power before shifted by the calculated ratio between the two RF power values to calculate the shifted RF power.

4. The magnetic resonance imaging apparatus according to claim 1, further comprising
a threshold setting unit configured to set the threshold to be a weight at which variation in the specific absorption ratio based on the RF power and the weight is smaller than or equal to or smaller than a second threshold.

5. The magnetic resonance imaging apparatus according to claim 4, wherein
the shifted RF power calculation unit calculates, when the weight of the imaging region of the object is smaller than or equal to or smaller than the threshold, the shifted RF power, and
the threshold setting unit sets a weight threshold for the imaging region.

6. The magnetic resonance imaging apparatus according to claim 1, wherein
the shifted RF power calculation unit measures the RF power before shifted at a time of imaging.

7. A magnetic resonance imaging apparatus comprising:
a specific absorption ratio calculation unit configured to calculate a specific absorption ratio based on a weight of an object or an imaging region of the object and correct the calculated specific absorption ratio based on the amount of correction according to the weight of the object to calculate a corrected specific absorption ratio; and
a display control unit configured to display the corrected specific absorption ratio on a display device.

8. A method for calculating specific absorption ratio in magnetic resonance imaging apparatus, comprising:
shifting RF power, when a weight of an object or an imaging region of the object is smaller than or equal to or smaller than a threshold, in accordance with a difference between the weight and the threshold to calculate shifted RF power;
calculating, when the weight is smaller than or equal to or smaller than the threshold, a specific absorption ratio based on the threshold and the shifted RF power; and
displaying the specific absorption ratio on a display device.
